(19) United States
(12) Patent Application Publication
(10) Pub. No.: US 2024/0368805 A1
(43) Pub. Date: Nov. 7, 2024

(54) METHOD FOR MANUFACTURING A SILICON INGOT FROM SURFACE-OXIDISED SEEDS

(71) Applicant: COMMISSARIAT A L'ENERGIE ATOMIQUE ET AUX ENERGIES ALTERNATIVES, Paris (FR)

(72) Inventors: Etienne PIHAN, Grenoble Cedex 09 (FR); Raphaël CABAL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/690,194

(22) PCT Filed: Sep. 9, 2022
(86) PCT No.: PCT/EP2022/075166

§ 371 Date: Mar. 7, 2024

(30) Foreign Application Priority Data
Sep. 10, 2021 (FR) 2109505

(51) Int. Cl. C30B 29/06; C30B 15/20; C30B 15/36

(52) U.S. Cl. CPC C30B 29/06; C30B 15/20; C30B 15/36

(57) ABSTRACT

The present invention relates to a method for producing a silicon ingot from a silicon melt by directional solidification, wherein the growth of the silicon ingot is initiated by bringing the silicon melt into contact with at least one silicon seed, characterised in that at least the surface of the seed brought into contact with the silicon melt is oxidised.

### TECHNICAL FIELD

The present invention relates to a novel process for manufacturing a silicon ingot, in particular by directional solidification by growth on seeds.

Such an ingot is advantageously intended to give, by cutting, silicon wafers of excellent crystalline quality. Such wafers are particularly advantageous in the context of the production of photovoltaic cells and modules.

### PRIOR ART

Photovoltaic energy by collecting solar radiation can be produced using a photovoltaic cell manufactured from a monocrystalline or polycrystalline silicon ingot. Such a silicon ingot is generally produced by solidification of molten silicon. It is then cut into wafers needed for the manufacture of photovoltaic cells.

Various types of processes for producing silicon ingots are known.

Firstly, pulling solidification methods generally involve bringing a seed into contact with a bath containing molten silicon, then solidifying the silicon out of the bath by moving the seed relative to the crucible containing the bath. The ingot thus grows progressively along the direction of movement of the seed, the molten material being “pulled” out of the bath.

As examples, mention may be made of the Czochralski process, also known as the “Cz process” or else the float zone process, also known as the “Fz process”.

Secondly, methods of directional solidification by growth on seeds typically involve the solidification, in a crucible, of molten silicon in contact with a silicon seed, fixed with respect to the crucible. For example, in case of a “mono-like” (ML) process of directional solidification by growth on seeds, monocrystalline silicon seeds of cuboid shape are positioned at the bottom of a crucible and form a tiling. By contact of the molten silicon with the seeds, grains grow along a favored solidification direction, and have substantially the same crystallographic orientation as the seeds from which they are derived. The silicon ingot obtained by this process generally has columnar grains which extend over the entire height of the ingot.

However, in one or other of these methods, problems of the structural degradation of the silicon seed(s) used to initiate ingot growth and of the appearance of dislocations, which are detrimental to the quality of the silicon ingot obtained, arise.

In particular, in the case of directional solidification by growth on seeds, the dislocations and crystal defects multiply from the bottom to the top of the solidified ingot, and thus lead to a portion at the top of the solidified ingot which is rich in dislocations and crystal defects and is consequently unusable for the exploitation thereof for the production of silicon wafers suitable for the preparation of PV cells.

There are many mechanisms responsible for the degradation of the seeds and they result ultimately in a mechanical deformation of the seeds [Krause] and/or by the introduction and multiplication of dislocations [Ekstrom].

For example, in the various techniques known as growth on seeds, proposed in the silicon literature for photovoltaic applications ([Khattak], [Stoddard], [Jouini], [Stoddard2], [Rost]), various sources of defects have been identified. Even in the case of absence of N and C contamination, in the absence of mechanical interactions between a crucible and the seeds, or in the absence of a tiling of multiple seeds (use of a single seed), heating a large Cz seed is sufficient for the formation of crystal defects therewithin [Stoddard2] [Rost]. The difficulty of heating a piece of silicon to the melting point without the appearance of dislocations is known [Mizuhara].

In the case of the Cz [Dash] and Fz [Werner] growth methods, the “Dash necking” technique is generally used in order to eliminate dislocations generated when the seed comes into contact with the molten mass of silicon, by carrying out an initial growth phase at high speed and with a small diameter. The “Dash necking” technique can thus be applied to the Cz and

Fz pulling methods, subject to significant variations in the parameters used. In the context of the implementation of these methods, preferentially the surface oxides of the seeds are removed to avoid poor epitaxy (microtwins and threading dislocations) [Dash] at the periphery of the seeds.

Obviously, such “Dash necking” conditions cannot, however, be used in the context of the manufacture of an ingot by growth on seeds, in particular for a “mono-like” process, neither in terms of growth rate, nor in terms of ingot size.

Moreover, the “Dash necking” technique is also unsuitable in cases where it is desired to optimize the productivity of silicon ingots, avoid a reduction in the diameter of the pulled ingot, use large-sized seeds and increase the dimensions of the silicon ingot.

To the knowledge of the inventors, the only techniques proposed to date for enabling dislocation-free growth and that do not use the “Dash necking” method, are based on the formation of a bulge for <110> pulling [Aubert] or else on immobilizing the dislocations by doping the seed and/or ingot (which doping is however excessive for most applications) [Taishi1] [Taishi2].

### SUMMARY OF THE INVENTION

The present invention aims to provide a new method to reduce the presence and multiplication of dislocations generated during the growth of a silicon ingot by directional solidification from one or more silicon seeds.

In particular, the invention aims to develop a process for preparing a silicon ingot of excellent structural quality, in particular with a reduced amount of dislocations, especially at the top of the solidified ingot, without however requiring the “Dash necking” technique.

As illustrated in the following examples, the inventors have shown, surprisingly, that it is possible to obtain a silicon ingot of better quality, in particular having a reduced number of crystal defects and dislocations, by using, for the growth of the silicon by directional solidification, one or more seeds of which the surface, intended to be brought into contact with the molten silicon, is oxidized beforehand.

Thus, the invention relates, according to one of its aspects, to a process for manufacturing a silicon ingot by directional solidification from molten silicon, wherein the growth of the silicon ingot is initiated by bringing the molten silicon into contact with at least one silicon seed, characterized in that at least the surface of said seed placed in contact with the molten silicon is oxidized.

In particular, said silicon seed is oxidized over the entire surface thereof.

The process of the invention may more particularly comprise the following steps:
(i) providing at least one silicon seed having, at least on the surface thereof intended to be brought into contact with the molten silicon, in particular on the entire surface thereof, a layer comprising, or even consisting of, a silicon oxide, said layer having in particular a thickness of strictly greater than 4 nm, in particular greater than or equal to 10 nm:
(ii) performing the directional solidification of silicon by bringing at least said surface-oxidized seed into contact with molten silicon.

In the remainder of the text, a “surface-oxidized seed” or more simply an “oxidized seed” denotes a silicon seed, at least one portion of the surface thereof intended to be brought into contact with the molten silicon during the growth of the silicon ingot by directional solidification, is oxidized, in particular, a silicon seed having, on at least the surface thereof intended to be brought into contact with the molten silicon, an “oxide layer” comprising, or even consisting of, a silicon oxide. In particular, the oxide layer may be a layer comprising, or even formed of, SiO₂.

In particular, the entire surface of said oxidized seed used according to the invention may be oxidized.

Said surface-oxidized seed(s) may be prepared, prior to being used in the directional solidification method, by a surface oxidation treatment of non-oxidized silicon seed(s), in particular of monocrystalline silicon seed(s), as detailed in the remainder of the text. The process according to the invention may thus comprise, prior to the directional solidification of the silicon, a surface oxidation treatment of a silicon seed, in particular of a monocrystalline silicon seed.

The surface oxidation treatment is more particularly a thermal treatment in an oxidizing atmosphere.

The process of the invention they use any method of directional solidification of silicon known to those skilled in the art, provided that it initiates the growth of the silicon ingot from bringing one or more silicon seeds into contact with molten silicon.

Directional solidification methods can be pulling methods, such as the Czochralski process or methods of directional solidification by growth on seeds.

In general, during the initiation of ingot growth by directional solidification, said seed(s) is/are brought to a temperature above or equal to 1200° C., preferably to a temperature that may range up to the melting point thereof, i.e. approximately 1415° C., when they are brought into contact with the molten silicon.

Advantageously, the process of the invention does not require the use of the “Dash necking” technique. It thus allows the use of directional solidification methods incompatible with the Dash necking technique.

The process of the invention thus proves to be particularly advantageous for allowing the formation of large ingots, for the implementation of directional solidification from a large seed or from a tiling of multiple seeds.

According to a particular embodiment, detailed more particularly in the remainder of the text, the process of the invention implements a solidification of the silicon ingot by growth on seeds, in particular from monocrystalline (“mono-like” or ML) silicon seeds.

As illustrated in the following examples, given by way of illustration for a “mono-like” method of directional solidification by growth on seeds, the use of surface-oxidized seeds according to the invention makes it possible to significantly reduce the phenomenon of multiplication of crystal defects and dislocations from the bottom to the top of the ingot, compared to an ingot obtained from seeds that are not surface-oxidized.

Without wishing to be bound by theory, the presence of an oxidized surface layer, in particular an SiO₂ layer, makes it possible to reduce the structural degradation of said Cz silicon seed(s) when they are heated to high temperature, in particular up to the melting point of silicon, and come into contact with the molten silicon during the initiation of the crystallization of the silicon ingot.

Thus, the silicon ingot, on conclusion of the directional solidification according to the process of the invention, has an improved quality, in particular a reduced amount of crystal defects and dislocations at the top of the ingot, compared to an ingot obtained from seeds of the same kind, but that are not surface-oxidized.

The process of the invention thus makes it possible to obtain a better overall homogeneity of the quality of the ingot over its entire height.

In particular, it can advantageously be used for the preparation of an ingot of large dimensions, in particular having a height, measured along the ingot growth direction, of between 100 and 400 mm, and a width, corresponding to the largest dimension measured in a plane orthogonal to the ingot growth direction, of between 400 and 2000 mm.

Advantageously, the quality of the ingot solidified from a surface-oxidized seed according to the invention is not affected when the gaseous environment during the directional solidification process is contaminated with nitrogen (via the presence of N₂, Si₃N₄) or carbon (via the presence of CO or an organic binder of Si₃N₄).

Other features, variants and advantages of the process for manufacturing a silicon ingot according to the invention will emerge more clearly on reading the description, the examples and figures which follow, which are given by way of illustration and do not limit the invention.

### BRIEF DESCRIPTION OF THE DRAWINGS

FIG. 1 shows, schematically and as a top view, the tiling in the bottom of the crucible used according to example 1;

FIG. 2 shows, schematically and in cross section, the crucible comprising the tiling of oxidized seeds used according to example 1:

FIG. 3 shows an image of photoluminescence imaging on the 4 end trimmings carried out at the top of the ingot, for the reference ingot (a) and for an ingot obtained according to test A in accordance with the invention (b) and the outlines of the surface areas counted as percentage of “defective” surface area:

FIG. 4 is a histogram showing the percentage of surface area affected by electrically active structural defects at the bottom (right) and at the top (left) of the ingot for the 4 bricks of the reference ingot and of the ingot produced according to test A in accordance with the invention:

FIG. 5 shows, schematically and as a top view, the tiling in the bottom of the crucible used according to example 2;

FIG. 6 shows an image of photoluminescence imaging on the 4 assembled end trimmings at the top of the ingot for ingot B obtained according to example 2 and counting of the defective surface areas:

FIG. 7 is a histogram showing the percentage of surface area affected by electrically active structural defects for the four end trimmings at the top of ingot B obtained according to example 2:

FIG. 8 shows the superposition image of the EDS mappings produced for ingot B obtained in example 2 (light portion: identification of the element oxygen):

FIG. 9 shows the graph of horizontal profile measurements of the elements Si and oxygen obtained by EDS mapping for ingot B obtained in example 2.

In the figures, the scales and proportions of the various elements have not been respected, for the sake of clarity of the drawing.

In the text that follows, the expressions “between . . . and . . . “, “ranging from . . . to . . . ” and “varying from . . . to . . . ” are equivalent and are intended to mean that the limits are included, unless mentioned otherwise.

### DETAILED DESCRIPTION

### Preparation of the Surface-Oxidized Seed

As indicated above, the process for producing a silicon ingot according to the invention uses one or more surface-oxidized seeds.

More particularly, the surface-oxidized seed used according to the invention has, at least on the surface thereof intended to be bought into contact with the molten silicon during the initiation of the solidification of the silicon ingot, a layer comprising, or even consisting of, a silicon oxide, hereinafter referred to as an “oxide layer”.

The surface oxide layer of said oxidized seed(s) may be a layer of silicon oxide of SiOx type, with x less than or equal to 2, preferably a layer of SiO₂.

Preferably, said silicon seed is oxidized over the entire surface thereof intended to be brought into contact with the molten silicon. In other words, the oxide layer extends over at least the entire surface of said seed intended to come into contact with the molten silicon. Preferably, the entire surface of said silicon seed(s) is oxidized. In other words, the surface-oxidized seed has an oxide layer over the entire surface thereof.

The surface-oxidized silicon seed(s), used according to the invention, can be prepared, prior to being used in the directional solidification method, by subjecting one or more silicon seeds, in particular monocrystalline silicon seeds, to a surface oxidation treatment. Thus, the process of the invention may more particularly comprise at least the steps consisting of:
subjecting one or more silicon seeds, in particular monocrystalline silicon seeds, to a surface oxidation treatment, in particular to a thermal oxidation treatment in an oxidizing atmosphere, said surface treatment being capable of forming on at least the surface of said seed(s) intended to be brought into contact with molten silicon, in particular on the entire surface of said seed(s), a layer comprising, or even consisting of, a silicon oxide; and
performing the directional solidification of silicon by bringing said surface-oxidized seed(s) into contact with molten silicon.

Said silicon seed(s), subjected to a prior surface oxidation treatment, may more particularly be seeds obtained from a silicon ingot produced using a Czochralski pulling technique (also referred to as a Cz ingot), or else “Fz” seeds, in other words, seeds obtained from an ingot produced according to a float zone process, also referred to as an “Fz” ingot.

It is understood that, depending on the directional solidification method used, one or more surface-oxidized silicon seeds, of suitable shape and dimensions, may be used for the production of the silicon ingot.

For example, in the case of the directional growth of the silicon ingot by a Czochralski method, the process of the invention then involves bringing a surface-oxidized single seed (mono-seed) into contact with a bath of molten silicon.

In the case of the production of the silicon ingot by a growth method by growth on seeds, in particular by a “mono-like” (or “ML-Si”) solidification method, as detailed in the remainder of the text, the process of the invention uses a tiling consisting of a single monocrystalline silicon seed or several monocrystalline silicon seeds, positioned at the bottom of a crucible in which a silicon feedstock will be heated. The single seed or, in the case of a tiling formed of several seeds, at least one of the seeds of said tiling, or even preferably all the seeds of said tiling, is then a surface-oxidized seed.

In the context of this variant, said seed(s) positioned at the bottom of the crucible to form the tiling are more particularly of right prism shape.

The term “right prism shape” is of course understood to mean a shape approximately of right prism type. In particular, the seeds have vertical or substantially vertical side walls (deviation of ±5°. Moreover, the seeds of the tiling in the bottom of the crucible have approximately flat surfaces, except for surface irregularities.

In the remainder of the text, the generally flat face of the seed facing the bottom of the crucible will be denoted as being the “base of the seed” and the face of the seed on the opposite side to the base of the seed, i.e. the face that will come into contact with the molten silicon feedstock, will be denoted as being the “upper face”.

As detailed below, the base of the seeds (respectively the upper face of the seeds) may be of varied shape, in particular of square or rectangular shape or else of parallelogram shape.

Preferably, it is of square or rectangular shape, the seeds then approximately having a cuboid shape.

Preferably, still within the context of the production of the silicon ingot by a growth technique by growth on seeds, the entire surface of the upper face of said oxidized seed(s) positioned in the bottom of the crucible suitable for the directional solidification, is oxidized.

In other words, said oxidized seed(s), positioned at the bottom of the crucible, have at least on their upper face an oxide layer, in particular a layer of silicon oxide, and more particularly of SiO₂.

In one particular embodiment, all the seeds forming the tiling in the bottom of the crucible are surface-oxidized. An oxide layer, in particular a silicon oxide layer, then extends over the entire surface at the bottom of the crucible defined by all the upper faces of the seeds forming the tiling at the bottom of the crucible, in other words, at the level of the entire surface of the seed tiling dedicated to coming into contact with the molten silicon bath.

As indicated above, said oxidized seed(s) used according to the invention may be prepared beforehand via a surface oxidation treatment.

The surface oxidation treatment is capable of generating, on at least one portion of the surface of the silicon seed, in particular on the entire surface of the silicon seed, a surface layer comprising, or even consisting of, a silicon oxide, in particular SiO₂, of desired thickness.

In particular, the oxidized surface layer must be thick enough not to be degraded before said silicon seed is brought into contact with the molten silicon during the initiation of the directional growth of the silicon ingot. The oxide layer must thus withstand the heating of the seed, prior to being brought into contact with the molten silicon, and more precisely heating of several hours that may range up to a temperature close to the melting point of silicon, or up to a temperature strictly below 1415° C.

Preferably, the oxide layer, in particular silicon oxide layer, of an oxidized silicon seed used according to the invention has a thickness strictly greater than 4 nm, in particular greater than or equal to 10 nm, in particular greater than or equal to 100 nm. In particular, the oxide layer, in particular silicon oxide layer, of an oxidized silicon seed used according to the invention has a thickness of greater than 100 nm, meaning a thickness strictly greater than 100 nm.

On the other hand, it is desirable that the oxide layer, in particular silicon oxide layer, of an oxidized seed according to the invention is not too thick so that it can dissolve in the bath of molten silicon, which is undersaturated with oxygen at the start of the growth of the silicon ingot, once growth has been initiated by bringing said oxidized seed into contact with the molten silicon.

Preferably, the thickness of the oxide layer, in particular silicon oxide layer, is thus less than or equal to 2 μm, in particular less than or equal to 1 μm and more particularly less than or equal to 600 nm. In particular, the thickness of the oxide layer, in particular silicon oxide layer, is less than 1 μm, meaning a thickness strictly less than 1 μm.

According to one particular embodiment, the oxide layer of said oxidized seed(s) used in the process of the invention has a thickness of between 10 nm and 2 μm, notably between 50 nm and 1 μm, in particular between 100 nm and 600 nm.

In particular, the oxide layer of said oxidized seed(s) used in the process of the invention has a thickness of greater than 100 nm and less than 1 μm, i.e. a thickness strictly greater than 100 nm and strictly less than 1 μm.

Advantageously, said oxidized seed(s) have an oxide layer of substantially constant thickness over the whole of the oxidized surface. The term “substantially constant thickness” is understood to mean that the thickness of the oxide layer varies by less than 20%, in particular by less than 10%, over the entire oxidized surface of the seed.

The thickness of the oxide layer can be measured by techniques known to those skilled in the art, for example by ellipsometry.

It is understood that the surface of the silicon seed to be oxidized, for example of the Cz monocrystalline silicon seed, may be subjected, prior to the oxidation treatment, to one or more surface treatment steps, for example to an etching surface treatment, such as, for example, with a potassium hydroxide solution.

The surface oxidation of said seed(s) can more particularly be carried out thermally in an oxidizing atmosphere. This oxidation heat treatment allows the growth of an oxide layer, in particular silicon oxide layer, directly on the silicon seed. More specifically, the oxide is formed both by the silicon of the seed and by the oxygen supplied by the oxidizing atmosphere.

The surface oxidation treatment of said seed(s) according to the invention differs in particular from the deposition of a silicon oxide film on top of the external surface of a substrate.

The surface thermal oxidation of said silicon seed(s) may be carried out by a dry process, in particular in an oxidizing atmosphere formed of a mixture of nitrogen and oxygen or argon and oxygen, or by a wet process, in particular in an atmosphere of hydrogen and oxygen or in air.

Preferably, the oxidation is carried out by a dry process. In this case, oxidation is generally carried out by bringing the surface of said seed to be oxidized into contact with a dry oxidizing gas, for example oxygen. The oxidizing atmosphere can be a mixture of nitrogen and oxygen, argon and oxygen, etc.

The oxidation can also be carried out by a wet process, that is to say by bringing the surface of said seed to be oxidized into contact with a gas containing or generating water vapor, such as a mixture of hydrogen and oxygen; air.

The thermal oxidation treatment in an oxidizing atmosphere can be carried out at a temperature between 700° C. and 1200° C., in particular between 800° C. and 1100° C. The oxidation treatment in an oxidizing atmosphere can be carried out for a period of time ranging from 1 minute to 400 hours, in particular from 10 minutes to 15 hours. The oxidation heat treatment can be carried out in a suitable oxidation furnace.

The surface oxidation treatment of a seed can more particularly be carried out by subjecting the surface of said seed to be oxidized to one or more oxidation sequences (or cycles), in particular between 1 and 5 oxidation sequences.

An oxidation sequence typically involves a temperature increase, followed by a hold at high temperature in an oxidizing atmosphere, then cooling.

Thus, the surface oxidation treatment of a seed according to the invention can comprise one or more oxidation sequences, an oxidation sequence comprising the following steps:
(a) heating said seed in order to reach the desired oxidation temperature:
(b) high-temperature oxidation in an oxidizing atmosphere; and
(c) cooling of said seed, preferably to room temperature.

The temperature increase step (a) can be carried out at a controlled rate and in a controlled atmosphere, such that it does not impact the surface of the seeds, preferably in an inert atmosphere.

For example, the temperature increase to reach an oxidation temperature of 800° C. can be carried out at a rate of from 3 to 5° C./minute in a mixture of air and nitrogen, up to a temperature of 700° C., then in an inert atmosphere, for example in N₂, from 700° C. to 800° C. Step (b) of high-temperature oxidation in an oxidizing atmosphere itself can be carried out under the abovementioned conditions. In particular, it can be carried out at a temperature of between 800° C. and 1100° C., for example at a temperature of 800° C. The duration of the step of oxidation in an oxidizing atmosphere may be between 1 minute and 400 hours, in particular between 10 minutes and 15 hours.

The seed can be cooled in step (c) in a controlled atmosphere and at a controlled rate. In particular, it can be cooled in an inert atmosphere, for example in a nitrogen atmosphere, from the oxidation temperature to a temperature of about 700° C., then cooled to ambient temperature in a mixture of air and nitrogen.

Steps (a) to (c) can be repeated until the desired thickness of the surface oxide layer is obtained.

At the end of the oxidation treatment, said seed(s) is/are thus provided with an oxidized surface layer.

The silicon seed(s) may be subjected to the surface oxidation treatment prior to being used in the device used to carry out the directional growth of the silicon ingot.

In particular, in the context of the implementation of a method of directional solidification by growth on seeds, said seed(s) may be subjected to the surface oxidation treatment, prior to being positioned at the bottom of the crucible suitable for the directional solidification.

According to an alternative embodiment, in the case of the implementation of a method of directional solidification by growth on seeds, said seed(s) forming the tiling in the bottom of the crucible may be subjected to the surface oxidation treatment, after being positioned at the bottom of the crucible.

In one particular embodiment, said surface-oxidized seed(s) are obtained by surface oxidation treatment of one or more silicon seeds positioned at the bottom of the crucible, said oxidizing treatment of said seeds advantageously being carried out at the same time as oxidizing treatment of the internal surface of the crucible, for example, to form a non-stick coating. For example, it can be carried out at the same time as the oxidizing heat treatment, for example carried out in air, of the internal surface of the crucible, in the context of the formation of a non-stick coating as described in application WO 2010/026342, or else to form a barrier layer as described in application WO 2015/036974 formed of grains of one or more materials chosen from SiC, Si and Si₃N₄, covered at least partially by a silica shell.

### Growth of the Silicon Ingot

The surface-oxidized seed(s), as described above, are used according to the process of the invention for the growth of a silicon ingot by directional solidification.

The process of the invention proves to be particularly advantageous in the case where it is not desired to implement the “Dash necking” technique, for example in the case where no dimensional limitation of the seed and of the ingot is desired.

Thus, the process of the invention can use any method of directional solidification of silicon known to those skilled in the art.

Generally speaking, directional solidification methods use either a pulling process or a process involving gradually cooling of the liquid bath, contained in a crucible, below its melting point, from one of its ends until it solidifies.

It is within the general knowledge of those skilled in the art to use apparatus suitable for the chosen growth method.

Irrespective of the directional solidification method used according to the invention, the growth of a silicon ingot by directional solidification is more particularly initiated by bringing at least one surface-oxidized seed raised to a temperature above or equal to 1200° C., in particular at a temperature ranging up to the melting point of said seed, notably that may reach 1415° C., into contact with a molten silicon bath.

As examples of pulling solidification methods, mention may be made of the Czochralski process, also known as the “Cz process” or else the float zone process, also known as the “Fz process”.

Preferably, the process of the invention carries out the directional solidification of a silicon ingot by growth on seeds.

As examples of a method of directional solidification by growth on seeds, mention may be made of the “mono-like” or “ML-Si” method of directional solidification by growth on seeds of a monocrystalline silicon ingot, or else the “NeoGrowth” method, described for example in US 2016/230307 A1.

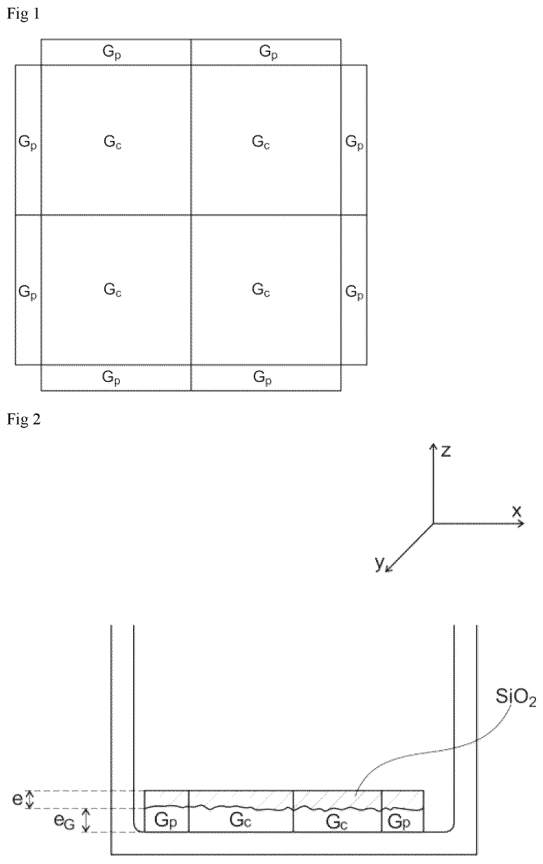

The description which follows relates to the embodiment variant of the process of the invention for a “mono-like” directional solidification by growth on seeds of a silicon ingot and is given with reference to FIGS. 1 and 2. It is understood that the invention is not limited to the embodiment variant described below, and that it can be implemented in any other method of directional growth of a silicon ingot.

As mentioned above, the directional solidification of a silicon ingot by growth on seeds conventionally uses one or more monocrystalline silicon seeds positioned in the bottom of a crucible.

The process of the invention, carrying out the directional solidification of the silicon ingot by growth on seeds may thus comprise more particularly the steps consisting of:
providing a crucible with a longitudinal axis (Z), the bottom of which comprises a single monocrystalline silicon seed, or a tiling of several monocrystalline silicon seeds, preferably of right prism shape, in particular of rectangular cuboid shape with square or rectangular base;
said single seed or at least one of the said seeds forming the bottom tiling of the crucible having, on at least the surface of its upper face, opposite the face facing the bottom of the crucible, in particular on the whole surface thereof, a layer comprising, or even consisting of, a silicon oxide, notably a silicon oxide layer:
performing the directional solidification of silicon by growth on seeds along a growth direction collinear to the axis (Z).

In particular, the entire surface of said single seed or at least one of said seeds forming the tiling in the bottom of the crucible is oxidized.

As described above, said surface-oxidized seed(s) may more particularly be obtained by a surface oxidation treatment, prior to being positioned at the bottom of the crucible: or after being positioned at the bottom of the crucible, the surface oxidation treatment of said seed(s) being carried out for example at the same time as an oxidizing treatment of the internal surface of the crucible, for example to form a non-stick coating on the internal surface of the crucible.

The invention also relates to a crucible, useful for the directional solidification by growth on seeds of a silicon ingot, the bottom of said crucible being completely or partly covered with a single monocrystalline silicon seed or a tiling of several monocrystalline silicon seeds, preferably in the form of a right prism: said single seed or at least one of said seeds forming the tiling having, on at least the surface of its upper face, opposite the face facing the bottom of the crucible, in particular on the whole surface thereof, a layer comprising, or even consisting of, a silicon oxide, in particular a silicon oxide layer.

Thus, the invention relates to a crucible provided with one or more seeds as defined above. The oxide layer is in particular as defined above.

In particular, said surface oxidized seed(s) are obtained by a surface oxidation treatment of one or more monocrystalline silicon seeds as described above.

The crucible is suitable for the directional solidification of a silicon ingot.

The longitudinal axis (Z) of the crucible denotes the line joining all of the bary centers of the cross sections of said crucible (walls of the crucible included). The longitudinal axis may more particularly be an axis of symmetry for the crucible.

Also, in the remainder of the text, and unless otherwise indicated, a seed and/or ingot and/or wafer are characterized for the orthogonal frame of reference of axes (x), (v) and (z), corresponding to the three main directions, respectively of the seed, of the ingot or of the wafer. Preferably, the axis (z) of a seed and/or of an ingot is collinear with the longitudinal axis (Z) of the crucible. In the case of a grid-type tiling of seeds, the directions (x) and (y) also correspond to the directions parallel to the grid lines, also referred to hereinafter as “tiling directions”.

As indicated above, said seed(s) used to form the tiling at the bottom of the crucible for directional solidification are preferably of right prism shape, in particular of rectangular cuboid shape with square or rectangular base.

They may have dimensions, along the directions (x) and (v) orthogonal to the longitudinal axis (Z) of the crucible, of between 20 mm and 1500 mm, in particular between 50 mm and 1300 mm.

They may have a thickness e_{G}, along the Z axis, of greater than or equal to 5 mm, in particular between 10 mm and 40 mm, in particular between 15 mm and 25 mm.

Preferably, in the case of tiling using at least two seeds, the seeds have similar or even identical thicknesses.

According to a first alternative embodiment, the process of the invention carries out the directional solidification of the silicon by growth on seeds, from a single seed, in particular of cuboid shape, positioned at the bottom of the crucible, at least the surface of the upper face of said seed, opposite the face facing the bottom of the crucible and intended to be brought into contact with the molten silicon bath, being oxidized.

Preferably, the single seed is oxidized over its entire surface.

The single seed positioned at the bottom of the crucible may have dimensions so as to cover virtually the entire surface of the bottom of the crucible.

According to another alternative embodiment, the process of the invention carries out the directional solidification of the silicon by growth on seeds, from a tiling formed of several monocrystalline silicon seeds, positioned in the bottom of the crucible, at least one of the seeds, preferably all of the seeds, constituting the tiling being surface-oxidized. In other words, at least the surface of the upper face, in particular the entire surface, of at least one of the seeds forming the tiling at the bottom of the crucible is oxidized. According to one particular embodiment, as mentioned above, all of the seeds constituting the tiling at the bottom of the crucible may be surface-oxidized seeds.

Preferably, the surface oxide layer of said oxidized seed(s) has a virtually constant thickness over the entire oxidized surface. In particular, all of the oxidized seeds used to form the tiling in the bottom of the crucible are prepared beforehand under identical surface oxidation treatment conditions, in order to ensure the formation of an oxide layer of substantially constant thickness on the surface of all of the oxidized seeds.

As indicated above, the oxide layer, in particular silicon oxide layer, present on at least the upper face of said oxidized seed(s) may have a thickness e of between 10 nm and 2 μm, in particular between 50 nm and 1 μm and more particularly between 100 nm and 600 nm.

The silicon seeds constituting the tiling at the bottom of the crucible are more particularly positioned in a contiguous manner.

The seed tiling, incorporating at least one surface-oxidized seed according to the invention, can have any crystallography.

According to a particular embodiment, as illustrated in example 1, the tiling of monocrystalline silicon seeds can be formed of one or more central seeds Gc and of one or more peripheral seeds Gp, adjacent to the seed(s) Gc. Said Gc and Gp seeds are in particular positioned and sized as described in application WO 2014/191899.

According to a particular embodiment, the tiling of seeds may comprise, or even be formed of seeds having crystal lattices that are symmetrical to one another. In other words, each seed has a crystal lattice symmetrical to the crystal lattice of the seed which is adjacent thereto, relative to the plane defined by the boundary between the two adjacent seeds. Such seed tiling is for example described in application WO 2014/191900.

In a particular embodiment, the tiling of the seeds can thus be formed of central seeds Gc and peripheral seeds Gp, each seed Gc having a crystal lattice symmetrical to the crystal lattice of the seed Gc which is adjacent thereto, relative to the plane defined by the boundary between the two adjacent seeds Gc.

Preferably, in the context of a tiling of seeds formed of one or more central seeds Gc and of one or more peripheral seeds Gp, all of the seeds Gc forming the central tiling are surface-oxidized.

Preferably, the seeds positioned on the bottom of the crucible, of rectangular cuboid shape with square or rectangular base, can form a tiling in the form of a regular grid with orthogonal directions (x) and (y) parallel to the edges of the seeds.

For example, it can be a tiling comprising or even being formed of a tiling in square shape formed of four seeds of rectangular cuboid shape with square base.

Those skilled in the art are able to adjust the operating conditions for the production of the silicon ingot by directional solidification by growth on seeds, from the crucible provided with the tiling of seeds according to the invention.

The directional growth of silicon by growth on seeds can be carried out in a crystallization furnace suitable for crystallization by growth on seeds.

In general, it carries out the following steps:
melting of a silicon feedstock in the crucible and partial melting of the seeds:
growth by directional solidification; and
cooling of the ingot.

The directional solidification may be carried out in a conventional directional solidification furnace, such as for example a crystallization furnace of HEM (Heat Exchange Method) type or of Bridgman type with set heating at the top and the sides, which makes it possible to crystallize the silicon feedstock with a controlled temperature gradient.

Generally, the directional solidification is carried out by firstly melting a silicon feedstock in the crucible. When the silicon is completely melted, and when the seeds begin to melt, the molten silicon is solidified, in a directional manner, at low speed (typically from 5 to 30 mm/h).

The directional solidification may be carried out by displacement of the heating system and/or by controlled cooling, enabling a gradual displacement of the solidification front (separation front between the solid phase and the liquid phase) toward the top of the crucible. The ingot obtained at the end of the directional solidification may then be cooled, in particular to room temperature (20° C.±5° C.).

Advantageously, since the process of the invention does not require the “Dash necking” method, it can be used to produce a large silicon ingot. In particular, the silicon ingot advantageously has a constant diameter over the entire height of the ingot. In particular, it may have a diameter greater than or equal to 400 mm, in particular between 400 mm and 2000 mm, notably between 400 mm and 1500 mm.

The height of the silicon ingot, defined along the Z axis, may be greater than or equal to 100 nm, in particular greater than or equal to 200 mm, notably between 300 mm and 500 mm.

After standard trimming of the peripheral zones of the ingot, the ingot can be cut into bricks according to techniques known to those skilled in the art. Silicon wafers for a PV application can then be produced from these bricks, according to conventional techniques known to those skilled in the art, notably by cutting the bricks, grinding the faces, trimming the top and bottom ends, to adjust the dimensions of the wafer, etc.

Advantageously, the silicon ingot obtained at the end of a solidification process according to the invention has a good crystalline quality.

In particular, a monocrystalline ingot obtained by directional solidification by growth on seeds according to the invention exhibits a small variation in the amount of crystal defects and dislocations between the bottom and the top of the ingot.

It is possible to use the entire height of the ingot for cutting bricks useful for the production of silicon wafers.

The invention will now be described by means of the examples that follow, which are given of course as nonlimiting illustrations of the invention.

### EXAMPLE

### Example 1

Two tests of directional solidification of a silicon ingot by growth on seeds were carried out using Cz seeds positioned at the bottom of a crucible with an internal cross section of 380×380× 400 mm³: reference ingot obtained from unoxidized seeds, and ingot A obtained according to the invention with surface-oxidized seeds.

For the two tests according to the invention, the seed tiling, as shown schematically in FIG. 1, consists of:
four central seeds Ge with width×length×thickness dimensions of (156-157)×(156-157)×(20-25) mm³, oriented (100) normal to the largest surface, lateral faces misoriented by about 15°(+3°) from the crystallographic orientation <100> and the surfaces of which deformed by cutting operations have been etched by a hot chemical solution using KOH:
eight peripheral seeds Gp sized as indicated in application

WO 2014/191900; with dimensions of (7-15)×(156-157)×(20-25) mm³.

These 12 seeds are assembled to generate symmetrical grain boundaries at each seed junction, the total misorientation 20 between the symmetrical crystal lattices of two seeds being 30°, according to the conditions defined in application WO 2014/191900 and also symmetrical quadruple junctions.

For the seeds of the reference test, etching with a KOH solution (over a thickness of greater than 50 μm) of the area work-hardened area by cutting operations is carried out.

For the seeds used for the preparation of an ingot A according to the process of the invention, each seed is prepared via the following steps:
etching of the work-hardened surface similar to that carried out for the seeds used for the solidification of the reference ingot:
forming a layer of SiO₂ on the surface of the seeds, with a thickness of greater than 300 nm according to the following conditions, in three oxidation sequences of respective duration: 5 hours, 5 hours and then one hour. The SiO₂ layer formed has a thickness of strictly less than 1 μm.

Each oxidation sequence includes:
a heating ramp (3 to 5° C./min in a mixture of air and N₂, from room temperature up to 700° C., then in N₂ from 700° C. to 800° C.);
oxidation (800° C. in a mixture of H₂ and O₂):
cooling in N₂ down to 700° C., then in air+N₂ below 700° C.

The seeds thus prepared, for the reference test and the test according to the invention, are assembled and sized above, in a crucible with an internal cross section of 380×380× 400 mm³.

The directional solidification of a silicon feedstock is then carried out by growth on seeds. The feedstock consists of a mass of silicon (65 kg) of electronic grade (9N), with an amount of boron suitable for obtaining a resistivity of 1-2 Ohm.cm after solidification.

The crystallization furnace used for the tests is a “Gen 2” size furnace (60 kg to 90 kg of feedstock) with three heating zones controlled in terms of temperature or power: a top heating zone, a bottom heating zone, and a side heating zone.

A silicon ingot is produced according to a thermal recipe suitable for obtaining quasi-monocrystalline ingots. The recipe includes directional melting of the feedstock and then of the surface of the seeds, directional solidification and cooling. It makes it possible to obtain a silicon ingot that meets the quality criteria of standard bricks.

### Evaluations

Four silicon bricks are cut along the planes defined by the boundary between the four central seeds, for example using a band saw.

The crystal quality of ML-Si ingots is evaluated, by photoluminescence imaging (BT Imaging LIS-R2 equipment), at the bottom (corresponding to the ingot bottom position, at an ingot height of 30 mm) and at the top (corresponding to the ingot top position, at an ingot height of 175 mm, for a total height of the ingot of approximately 205 mm) of the bricks obtained from the cutting of each ingot.

The photoluminescence imaging makes it possible to identify the surface covered with crystal defects, the photoluminescence signal being, under the measurement conditions [Trupke], proportional to the local lifetime of the carriers.

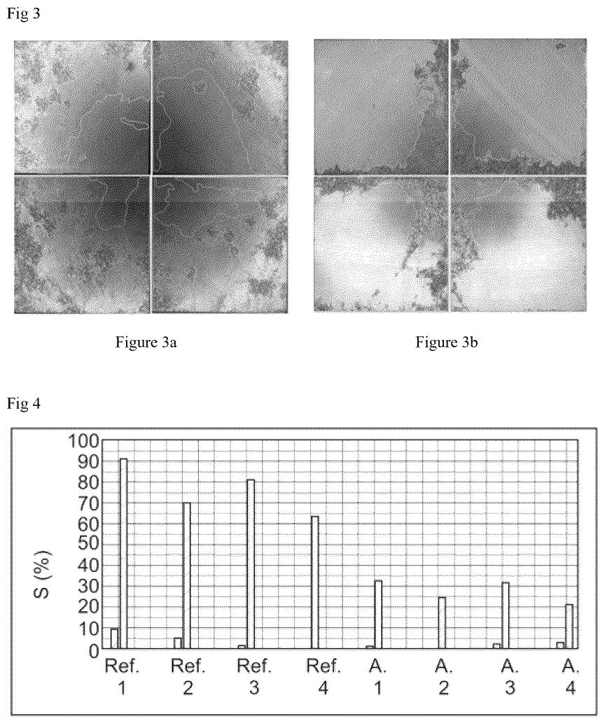

Counting of the surface area affected by crystal defects is carried out by image processing using ImageJ software. A raw photoluminescence image and the outlines of the surface areas counted as “defective” surface areas are shown in FIG. 3, for an end trimming in the top position a brick of the reference ingot (a) and of a brick of ingot A produced according to the process of the invention (b).

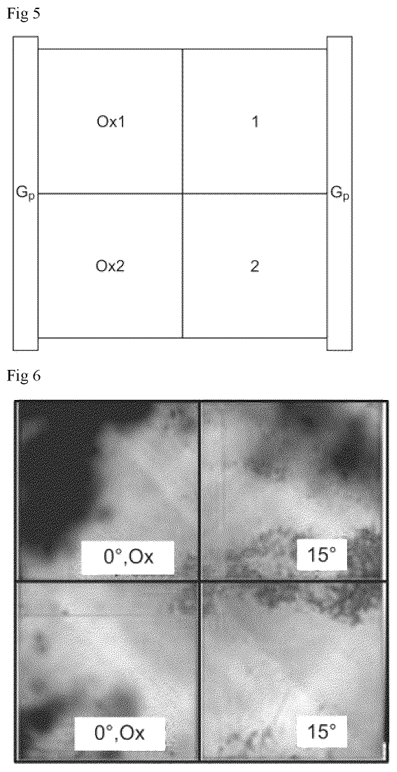

The measurements for counting the surface area affected by electrically active structural defects by this method are summarized in FIG. 4, for the four bricks of the reference ingot and of ingot A obtained according to the process of the invention, in the ingot bottom position (left columns) and ingot top position (right columns).

### CONCLUSIONS

For ingot A obtained from surface-oxidized seeds according to the invention (test A), defects remain present at the bottom of the ingot, but the defective surface area at the top of the ingot is significantly reduced compared to the defective surface area obtained for the ingot using seeds without prior oxidation treatment.

In addition, the defective surface area is more homogeneous (very similar on each brick at the top of the ingot) and the spatial distribution is drastically different from that observed for bricks obtained from the reference ingot.

The results obtained for bricks from the reference ingot are representative of the phenomenon of defect multiplication from bottom to top of an ingot obtained by directional solidification by growth on seeds. With this specific crystallography of the seed tiling used, the defects multiply greatly at the top of the ingot over the periphery of the ingot, with a low density of defects at the center of the ingot, including above the tiling junctions.

On the other hand, in the case of ingot A obtained from surface-oxidized seeds according to the invention, the periphery and the center of the bricks are free of defects while defects are observed above the junctions of the central seeds.

The spatial distribution of the zones with defects/defect-free zones observed for ingot A obtained according to the process of the invention is unusual with this seed crystallography: it reflects differences in the mechanisms of formation of crystal defects during the growth of the mono-like ingot on top of surface-oxidized seeds.

In particular, the use of surface-oxidized seeds makes it possible to significantly reduce the defect multiplication from the bottom to the top of the ingot.

### Example 2

A silicon ingot B is prepared according to the process of the invention from oxidized seeds by directional solidification by growth on seeds using Cz seeds (7 kg) placed at the bottom of a crucible with an internal cross section of 380×380× 400 mm³.

The seed tiling, as shown in FIG. 5, includes:
two oxidized seeds according to the invention, denoted 0×1 and 0×2, with dimensions of (156-157)×(156-157)×(20-25) mm³; and
two unoxidized seeds, denoted 1 and 2, with dimensions of (156-157)×(156-157)×(20-25) mm³.

The crystallography of the two sets of seeds is different; and several types of seed junctions result therefrom.

The type of junction differs due to the nature of the facing surfaces (unoxidized seed/oxidized seed or unoxidized seed/unoxidized seed or oxidized seed/oxidized seed) and due to the crystallography, in particular the approximate angle) (+3° of misorientation of the lateral faces of the facing seeds (0°/0°(15°/15°(0°/15°.

In addition, peripheral seeds Gp with approximate dimensions of (330-335)×(15-17)×(20 mm) are positioned on two opposite faces as shown in FIG. 5.

This seed tiling crystallography will be described as “arbitrary” hereinafter.

The oxidized seeds (0×1 and 0×2) are prepared by surface etching of the seeds Cz with a KOH solution, then subjecting to a 15-hour wet thermal oxidation in three 5-hour sequences, resulting in a layer of SiO₂ with a thickness greater than 500 nm. The SiO₂ layer formed has a thickness of strictly less than 1 μm.

Each oxidation sequence includes:
heating ramp (3 to 5° C./min in a mixture of air and N₂, from room temperature up to 700° C., then in N₂ from 700° C. to 800° C.);
oxidation (800° C. in a mixture of H₂ and O₂);
cooling in N₂ down to 700° C. then in air+N₂ down to room temperature.

The seeds thus prepared for the reference test and the test according to the invention are assembled and sized as described above, in a crucible with an internal cross section of 380× 380× 400 mm³.

The directional solidification of a silicon feedstock is then carried out by growth on seeds, in a furnace as described in example 1. The feedstock consists of 63 kg of silicon of electronic grade (9-12N), with an amount of boron suitable for obtaining a resistivity of 1-2 Ohm.cm after solidification.

### Evaluations

Four silicon bricks are cut along the planes defined by the boundary between the four central seeds, for example using a band saw.

The crystalline quality of the silicon ingot obtained is evaluated by photoluminescence imaging, as described in example 1, at the top of the ingot (at a height of 175 mm for a total ingot height of approximately 205 mm).

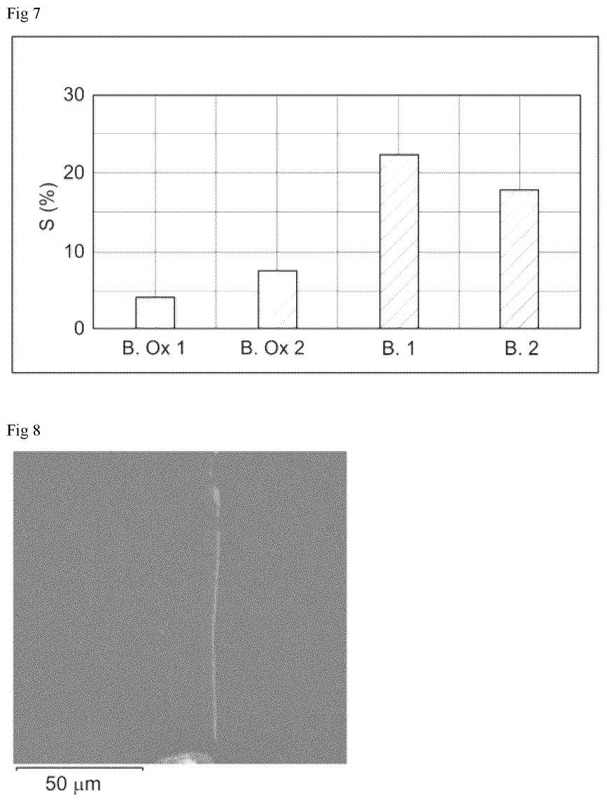

As seen in FIGS. 6 and 7, the defective surface area at the top of the ingot, in the zones of the ingot located above the oxidized initial seeds (0×1 and 0×2) is smaller than that observed in the zones of the ingot located above the unoxidized initial seeds 1 and 2.

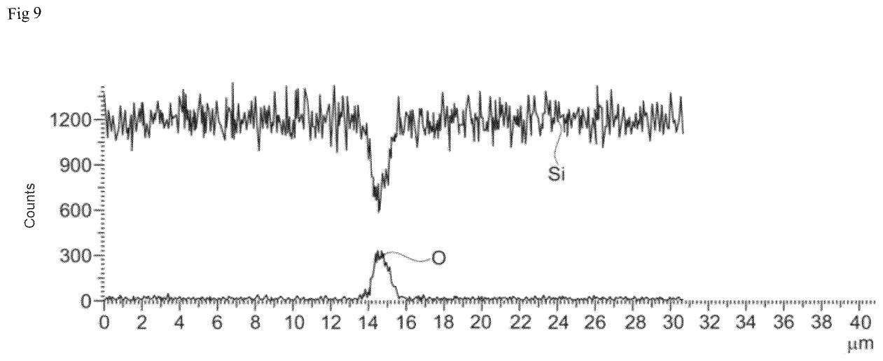

The presence of oxide in the ingot is studied by energy dispersive X-ray spectroscopy (EDS) mapping, and establishing the corresponding chemical profile (Si and O elements) at an unmelted but infiltrated unoxidized seed/oxidized seed junction after growth of the ML-Si ingot (FIGS. 8 and 9).

Close to the limit of the unmelted bottom zone of the seeds (distance of less than 200 μm), the discontinuous presence of an oxide is noted. No trace of the oxide was found at the melted interface (upper surface of the seed), suggesting that the oxide was completely dissolved by the liquid silicon bath.

### List of Cited Documents

[Dash] Dash, J. Appl. Phys., No. 4, Vol. 30, p. 459-474, 1959;
[Werner] Nico Werner Diplom-Ingenieur, genehmigte Dissertation, Analysis and Automation of the crucible-free Floating Zone (FZ) Growth of Silicon Crystals, 2014, Berlin. IKZ. Verlag: epubli GmbH, Berlin:
[Krause] Krause et al., Energy Procedia, vol. 92, p. 833-838, 2016;
[Ekstrom] Ekstrom et al., Phys. Status Solidi A, vol. 212, no 10, p. 2278-2288, 2015;
[Khattak] Khattak et al., (1987); Silicon Processing for Photovoltaics II. Khattak, C. P.; Ravi, K. V., eds. Elsevier Science Publishers; pp. 153-183.
[Jouini] Jouini et al., Progress in Photovoltaics: Research and Applications, 20 (2012) 735-746:
[Stoddard] Stoddard et al., (2008) Solid State Phenomena, 131-133, pp. 1-8.
[Stoddard 2] Stoddard et al., Prog Photovolt Res Appl. 2018:1-8:
[Rost] Rost et al., Journal of Crystal Growth 500 (2018) 5-10.
[Taishi 1] Hoshikawa et al., Journal of Crystal Growth 275 (2005) 276-282
[Taishi 2] Yu et al., J. Appl. Phys. Vol. 42 (2003) pp. L 1299-L 1301
[Aubert] Aubert et al., Revue de Physique Appliquée, 1987, 22 (7), pp. 515-518:
[Mizuhara] Mizuhara et al., 2003, Jpn. J. Appl. Phys. 42 1133;
[Trupke| Trupke et al., Photoluminescence Imaging for Photovoltaic Applications. Energy Procedia. Volume 15, 2012. Pages 135-146. ISSN 1876-6102.

1. A process for manufacturing a silicon ingot by directional solidification from molten silicon, comprising:
initiating growth of the silicon ingot by bringing the molten silicon into contact with at least one silicon seed, and
oxidizing at least a surface of the seed placed in contact with the molten silicon, the surface-oxidized seed having, at least on the surface thereof brought into contact with the molten silicon, an oxide layer comprising, a silicon oxide having a thickness of greater than 100 nm and less than 1 μm.

2. The process as claimed in claim 1, comprising:
(i) providing the at least one silicon seed having, at least on the surface thereof intended to be brought into contact with the molten silicon, the oxide layer; and
(ii) performing directional solidification of silicon by bringing at least said the surface-oxidized seed into contact with the molten silicon.

3. The process as claimed in claim 2, said process comprising, prior to the directional solidification of the silicon, a surface oxidation treatment of the at least one silicon seed.

4. The process as claimed in claim 3, wherein the surface oxidation treatment is carried out thermally in an oxidizing atmosphere.

5. The process as claimed in claim 3, wherein the surface oxidation treatment of said at least one silicon seed is carried out by subjecting the surface of the at least one silicon seed to be oxidized to one or more oxidation sequences, an oxidation sequence comprising the following steps:
(a) heating said at least one silicon seed in order to reach a desired oxidation temperature;
(b) conducting a high-temperature oxidation in an oxidizing atmosphere; and
(c) cooling of said at least one silicon seed.

6. The process as claimed in claim 4 or 5, wherein the thermal oxidation treatment is carried out by a dry process.

7. The process as claimed in claim 1, wherein said surface oxide layer has a thickness of less than or equal to 600 nm.

8. The process as claimed in claim 1, said process comprising:
providing a crucible with a longitudinal axis, a bottom of which comprises a single monocrystalline silicon seed, or a tiling of several monocrystalline silicon seeds;
the single seed or at least one of the seeds forming the bottom tiling of the crucible having, on at least a surface of its upper face, opposite a face facing the bottom of the crucible, a layer comprising, a silicon oxide; and
performing directional solidification of silicon by growth on seeds along a growth direction collinear to the axis.

9. The process as claimed in claim 8, wherein said surface-oxidized seed(s) are obtained by a surface oxidation treatment, prior to being positioned at the bottom of the crucible; or after being positioned at the bottom of the crucible.

10. A crucible provided with one or more seeds, configured for directional solidification by growth on seeds of a silicon ingot, a bottom of the crucible being completely or partly covered with a single monocrystalline silicon seed or a tiling of several monocrystalline silicon seeds; the single seed or at least one of the seeds forming the tiling having, on at least a surface of its upper face, opposite a face facing the bottom of the crucible, a layer comprising a silicon oxide, with a thickness of greater than 100 nm and less than 1 μm.

11. The crucible as claimed in claim 10, the surface-oxidized seed(s) being obtained by a surface oxidation treatment of one or more monocrystalline silicon seed(s) comprising:
initiating growth of the silicon ingot by bringing molten silicon into contact with at least one silicon seed,
oxidizing at least a surface of the seed placed in contact with the molten silicon, the surface-oxidized seed having, at least on the surface thereof brought into contact with the molten silicon, an oxide layer comprising a silicon oxide having a thickness of greater than 100 nm and less than 1 μm,
performing directional solidification of silicon by bringing at least the surface-oxidized seed into contact with the molten silicon, and
prior to the directional solidification of the silicon, performing a surface oxidation treatment of the at least one silicon seed,
wherein the surface oxidation treatment is carried out thermally in an oxidizing atmosphere.

12. The process as claimed in claim 1, comprising the oxide layer consisting of a silicon oxide.

13. The process as claimed in claim 2, comprising providing the at least one silicon seed having the oxide layer on the entire surface of the at least one silicon seed.

14. The process as claimed in claim 4, comprising carrying out the thermal oxidation treatment at a temperature of between 700° C. and 1200° C. for a period of time ranging from 10 minutes to 15 hours.

15. The process as claimed in claim 4, comprising carrying out the thermal oxidation treatment at a temperature of between 800° C. and 1100° C. for a period of time ranging from 10 minutes to 15 hours.

16. The process as claimed in claim 6, wherein the thermal oxidation treatment is carried out in an oxidizing atmosphere formed of a mixture of nitrogen and oxygen or argon and oxygen.

17. The process as claimed in claim 4, wherein the thermal oxidation treatment is carried out by a wet process in an atmosphere of hydrogen and oxygen or in air.

18. The process as claimed in claim 8, wherein the bottom comprises tiling of several monocrystalline silicon seeds in a right prism shape with a square or rectangular base.

19. The process as claimed in claim 9, wherein the surface oxidation treatment is carried out at a same time as an oxidizing treatment of an internal surface of the crucible to form a non-stick coating on the internal surface of the crucible.

20. The crucible as claimed in claim 10, wherein:
the bottom of the crucible is in the form of a right prism; and
the single seed or at least one of the seeds forming the tiling have the layer on an entire surface thereof.
